(19) United States
(12) Patent Application Publication
(10) Pub. No.: US 2025/0120222 A1
(43) Pub. Date: Apr. 10, 2025

(54) LIGHT-EMITTING DEVICE AND LIGHT-EMITTING APPARATUS

(71) Applicant: XIAMEN SAN'AN OPTOELECTRONICS CO., LTD., Xiamen (CN)

(72) Inventors: Sihe CHEN, Xiamen (CN); Yashu ZANG, Xiamen (CN); Weichun TSENG, Xiamen (CN); Shaohua HUANG, Xiamen (CN); Chi -Ming TSAI, Xiamen (CN); Chung-ying CHANG, Xiamen (CN); Su-Hui LIN, Xiamen (CN); Siyi LONG, Xiamen (CN)

(21) Appl. No.: 18/984,512

(22) Filed: Dec. 17, 2024

Related U.S. Application Data
(63) Continuation-in-part of application No. PCT/CN2022/137608, filed on Dec. 8, 2022.

(51) Int. Cl. H10H 20/819; H10H 20/831; H10H 20/857; H10H 20/858

(52) U.S. Cl. CPC H10H 20/819; H10H 20/831; H10H 20/857; H10H 20/8582

(57) ABSTRACT

A light-emitting device includes a semiconductor epitaxial structure including a first semiconductor layer, an active layer, and a second semiconductor layer sequentially stacked in such order in a stacking direction, and including a plurality of through holes. The through holes extend downwardly in a direction from the second semiconductor layer to the first semiconductor layer. The through holes expose a portion of a surface of the first semiconductor layer. The light-emitting device has an ampacity. Each of the through holes has a first radius. A ratio of the first radius to the ampacity ranges from 0.1 to 0.4. A light-emitting apparatus including the light-emitting device is also provided.

### CROSS-REFERENCE TO RELATED APPLICATION

This application is a continuation-in-part (CIP) of International Application No. PCT/CN2022/137608, filed on Dec. 8, 2022, the entire disclosure of which is incorporated by reference herein.

### FIELD

The disclosure relates to semiconductor manufacturing, and more particularly to a light-emitting device and a light-emitting apparatus.

### BACKGROUND

A light-emitting diode (LED) is a semiconductor device made of GaN, GaAs, GaP, GaAs, etc., and has a P/N junction that emits light. The light-emitting diode has several advantages such as high luminous intensity, high efficiency, small size, long lifespan, etc., and is considered to be one of the light sources having the most potential. The light-emitting diode is commonly used in lighting, monitoring and command, high-definition broadcasting, high-end theater, office display, conference communication, virtual reality, etc.

In recent years, ultraviolet LEDs (UV LEDs), in particular deep ultraviolet LEDs, have attracted great attention and become a new research topic. Throughout the developmental process, researchers found a UV LED needs a thinner chip for light exiting due to severe light absorption of its material. Such requirement demands a p-type semiconductor layer, an n-type semiconductor layer, and an active layer to be thinner as well. At the same time, because the p-type semiconductor layer has a high doping concentration and needs a low-temperature environment for growth, an atomic mobility during the growth is insufficient, thereby resulting in various defects. The defects may accelerate formation of burst points. If thicknesses of light-emitting materials of a standard light-emitting diode were used in the UV LED, temperature of the P/N junction may rise due to excessive photothermal conversion, thereby lowering lifespan of the light-emitting diode. The abovementioned problems bring challenges to an anti-ESD (electro-static discharge) performance of the UV LED.

### SUMMARY

Therefore, an object of the disclosure is to provide a light-emitting

device and a light-emitting apparatus that can alleviate at least one of the drawbacks of the prior art.

According to an aspect of the disclosure, the light-emitting device includes a semiconductor epitaxial structure including a first semiconductor layer, an active layer, and a second semiconductor layer sequentially stacked in such order in a stacking direction, and including a plurality of through holes. The plurality of through holes extend downwardly in a direction from the second semiconductor layer to the first semiconductor layer. The plurality of through holes expose a portion of a surface of the first semiconductor layer. The light-emitting device has an ampacity. Each of the plurality of through holes has a first radius. A ratio of the first radius to the ampacity ranges from 0.1 to 0.4.

According to another aspect of the disclosure, a light-emitting apparatus including the light-emitting device is also provided.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic top view of a light-emitting device according to a first embodiment of the present disclosure.

FIG. 2 is a schematic sectional view taken along line F-F of FIG. 1.

FIG. 3 illustrates thermal resistance curves of the present disclosure and a conventional light-emitting device.

FIG. 4 is a graph illustrating a relationship between ratio of radius to ampacity and electroluminescence efficiency.

FIG. 5 is a schematic top view of a light-emitting device according to a second embodiment of the present disclosure.

FIG. 6 is a schematic sectional view taken along line F-F of FIG. 5.

FIG. 7 is a schematic view illustrating protrusions being off-center in through holes of the light-emitting device according to the second embodiment of the present disclosure.

FIG. 8 is a schematic view illustrating the light-emitting device having recess structures according to the second embodiment of the present disclosure.

FIG. 9 is an enlarged schematic view of the protrusions having cover electrodes according to the second embodiment of the present disclosure.

FIGS. 10 to 13 are schematic diagrams illustrating a method for manufacturing the light-emitting device according to the second embodiment of the present disclosure.

FIG. 14 is a schematic top view of a light-emitting device according to a third embodiment of the present disclosure.

FIG. 15 is schematic sectional view taken along line F-F of FIG. 14.

FIG. 16 is a schematic view of the light-emitting device of FIG. 5 under a coordinate system.

FIG. 17 is a schematic view of the light-emitting device of FIG. 5 having a first circle and a second circle.

FIG. 18 is a schematic view illustrating an arrangement of the through holes according to the third embodiment of the present disclosure.

FIG. 19 is a graph illustrating a relationship between operating voltage and current of each of the present disclosure and the conventional light-emitting device.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

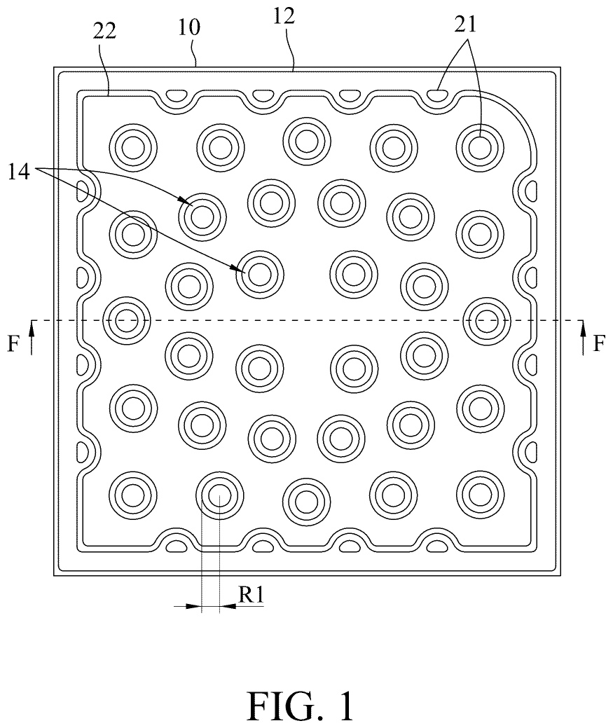

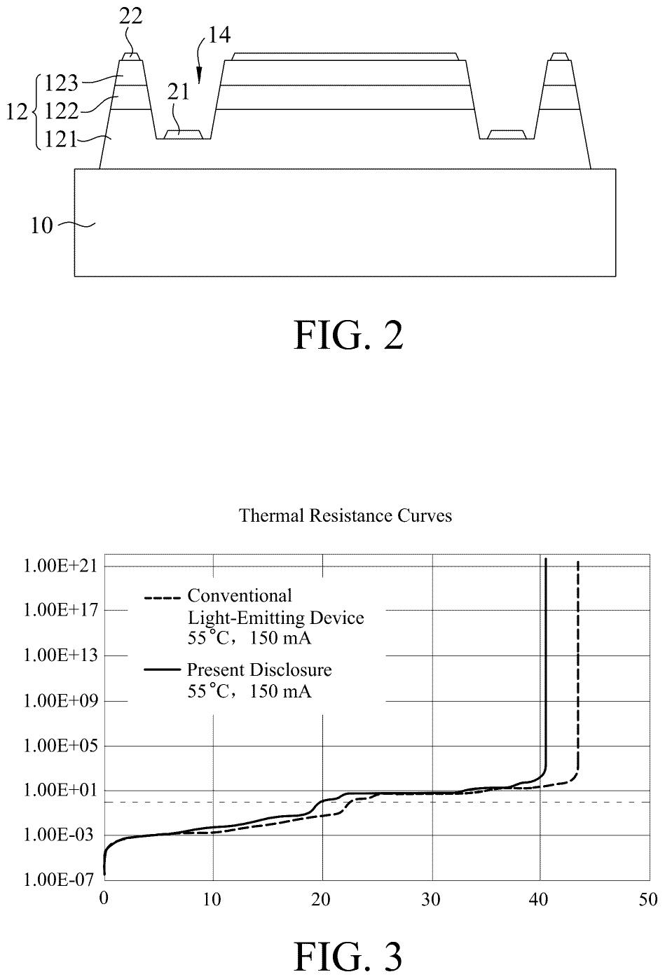

Referring to FIGS. 1 and 2, FIG. 1 is a schematic top view of a light-emitting device according to a first embodiment of the disclosure, and FIG. 2 is a schematic view taken along line F-F of FIG. 1. According to a first embodiment, the light-emitting device includes a substrate 10, a semiconductor epitaxial structure 12, a first electrode 21, and a second electrode 22.

The substrate 10 may be an insulating substrate. In some embodiments, the substrate 10 may be a transparent substrate or a semi-transparent substrate. In this embodiment, the substrate 10 is a sapphire substrate. In some embodiments, the substrate 10 may be a patterned sapphire substrate, but is not limited thereto. The substrate 10 may also be made of a conductive material or a semiconductor material. For example, materials of the substrate 10 may include silicon carbide, silicon, magnesium-aluminum oxide, magnesium oxide, lithium-aluminum oxide, aluminum-gallium oxide, and gallium nitride, or combinations thereof. In some embodiments, the substrate 10 may be thinned or removed for forming of a thin-film light-emitting device.

The semiconductor epitaxial structure 12 is disposed on the

substrate 10. The semiconductor epitaxial structure 12 includes a first semiconductor layer 121, an active layer 122, and a second semiconductor layer 123 sequentially stacked in such order in a stacking direction. That is to say, the first semiconductor layer 121 is disposed between the substrate 10 and the active layer 122, and the active layer 122 is disposed between the first semiconductor layer 121 and the second semiconductor layer 123.

The first semiconductor layer 121 may be an n-type semiconductor layer that provides electrons to the active layer 122 under an applied current. In some embodiments, the first semiconductor layer 121 includes an n-type doped nitride layer. The n-type doped nitride layer may include n-type impurities from group IV semiconductor materials. The n-type impurities may include Si, Ge, Sn, or combinations thereof. In some embodiments, a buffer layer is disposed between the first semiconductor layer 121 and the substrate 10 to reduce lattice mismatch between the substrate 10 and the first semiconductor layer 121. The buffer layer may be an unintentionally doped GaN layer or an unintentionally doped AlGaN layer. The first semiconductor layer 121 may also be bonded to the substrate 10 by the bonding layer.

The active layer 122 may have a quantum well structure. In some embodiments, the active layer 122 may have a multiple quantum well structure that includes a plurality of well layers and a plurality of barrier layers that are alternately stacked. For example, the active layer 122 may have a GaN/AlGaN multiple quantum well structure, an InAlGaN/InAIGaN multiple quantum well structure, or an InGaN/AlGaN multiple quantum well structure. In addition, compositions and thicknesses of the wells layers in the active layer 122 determine a wavelength of light generated. Depth and thickness of the quantum well structure, the number of pairs of the well layers and the barrier layers, etc. may be adjusted to improve light-emitting efficiency of the active layer 122. In some embodiments, the light-emitting device is a ultra-violet (UV) light-emitting device and emits light having a wavelength that ranges from 220 nm to 385 nm.

The second semiconductor layer 123 may be a p-type semiconductor layer that provides holes to the active layer 122 under an applied current. In some embodiments, the second semiconductor layer 123 includes a p- type doped nitride layer. The p-type doped nitride layer may include p-type impurities. The p-type impurities may include Mg, Zn, Be, or combinations thereof. The second semiconductor layer 123 may be a single-layered structure or a multilayered structure having different compositions. In addition, configuration of the semiconductor epitaxial structure 12 is not limited thereto, and may vary based on actual needs.

The semiconductor epitaxial structure 12 includes a plurality of through holes 14. Each of the through holes 14 extends downwardly in a direction from the second semiconductor layer 123 to the first semiconductor layer 121, and each of the through holes 14 exposes a portion of a surface of the first semiconductor layer 121. First electrodes 21 are disposed in the through holes 14, respectively. When the semiconductor epitaxial structure 21 is viewed from above the light-emitting device, the through holes 14 are arranged in arrays, and are disposed in the second semiconductor layer 123. That is to say, the through holes 14 are surrounded by the second semiconductor layer 123. In this embodiment, the through holes 14 are disposed in a multi-hole layout; compared to a conventional a finger-shaped layout, the multi-hole layout can improve current spreading and reduce occurrence of burst points. The conventional finger-shaped layout may cause current crowding at junctions in a P/N semiconductor layer, thereby causing burst points under current impulse or thermal shock. Distribution of the through holes 14 and a size and a shape of each of the through holes 14 are not limited to those shown in the figures, and may be designed according to an actual shape and size of a chip.

When the semiconductor epitaxial structure 12 is viewed from above the light-emitting device, each of the through holes 14 has a first radius (R1). In this embodiment, each of the through holes 14 has a round shape, and the first radius (R1) is a radius of each of the round shapes. However, a shape of each of the through holes 14 is not limited thereto. When each of the through holes 14 has a square-like shape or an irregular closed-loop shape, the first radius (R1) may be approximated by taking a radius of an internal circle of the square-like shape or the irregular closed-loop shape. In some embodiments, to avoid current crowding, the first radius (R1) ranges from 6 μm to 150 μm. In some embodiments, the first radius (R1) ranges from 7 μm to 90 μm and from 15 μm to 40 μm, thereby improving electrical performance of the light-emitting device. To improve thermal and electrical performances of the light-emitting device, a total area the through holes 14 occupies 10% to 50% of an area of the semiconductor epitaxial structure 12. As shown in Table 1 below, different ratios of the total area of the through holes 14 to the area of the semiconductor epitaxial structure 12 are listed and compared against each other for finding an optimal ratio, thereby further improving an operating voltage of the light-emitting device, increasing luminance flux and electroluminescence efficiency, and enhancing electrical overstress (a higher value of the electrical overstress represents more impact resistance). In some embodiments, the total area of the through holes 14 occupies 26% to 34% of the area of the semiconductor epitaxial structure 12, and the electroluminescence efficiency of the light-emitting device is better when the ratio falls within this range.

It should be noted that an area of each of the through holes 14 may refer to an area of a bottom of each of the through holes 14 (where a corresponding one of the first electrodes 21 is provided) in FIG. 2. Because the bottom of each of the through holes 14 is closer to the first semiconductor layer 121, an area of the bottom of each of the through holes 14 can better reflect the characteristics of each of the through holes 14. However, the present disclosure is not limited to such. In other embodiments, the area of each of the through holes 14 may refer to an area of a top of each of the through holes 14 (in an upper surface of the second semiconductor layer 123) in FIG. 2.

TABLE 1

| | Area Ratio (ratio of the | | | | |
|---|---|---|---|---|---|
| | area of the through holes | | | | |
| | to the area of the | Forward | | | |
| | semiconductor epitaxial | Voltage | Luminance | Wall-Plug | Electrical |
| | structure (%) | (M) | Flux (mW) | Eficiency (%) | Overstress (V) |
| Embodiment 1 | 26.2 | 5.80 | 22.1 | 2.5 | 18-20 |
| Embodiment 2 | 29.0 | 5.80 | 21.9 | 2.5 | 16-18 |
| Embodiment 3 | 31.1 | 5.70 | 24.8 | 2.9 | 21-23 |
| Embodiment 4 | 32.1 | 5.81 | 21.9 | 2.5 | 18-21 |
| Conventional light- | 38.8 | 6.07 | 20.5 | 2.3 | 10-15 |
| emitting device | | | | | |

Referring to FIG. 3 (the horizontal axis represents thermal resistance and the vertical axis represents thermal capacitance), the present disclosure improves the packaging thermal resistance as compared to a conventional light-emitting device by reducing the thermal resistance by approximately 3 K/W to 3.5 K/W, thereby improving stability of the light-emitting device.

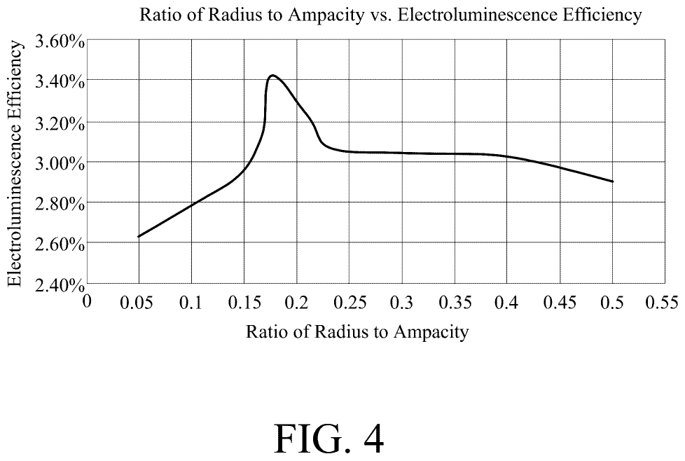

Compared to the conventional light-emitting device, considering that a large difference exists in the spreading ability at a p-side of the UV light-emitting device, more n-regions need to be introduced to shorten conduction at the p-side, by virtue of a ratio of the first radius (R1) to an ampacity ranging from 0.1 to 0.4, conduction of carriers is enhanced, regional current density is more uniform, heat caused by a concentration of current is avoided, holes burnt out of the active layer 122 are prevented, a direct downward electrical damage is avoided (the direct downward electrical damage can be understood as a direct concentration of current in the case where the semiconductor epitaxial structure 12 has a poorer lateral spreading performance, thereby causing current crowding), and a direct breakdown of a P/N junction is avoided, thereby improving an anti-ESD performance of the light-emitting device. Referring to FIG. 4 (the horizontal axis is the ratio of the first radius (R1) to the ampacity, and the vertical axis is the electroluminescence efficiency), effect of the ratio of the first radius (R1) to the ampacity on the electroluminescence efficiency is shown. Considering that the UV light-emitting device adopts a heterojunction structure of P-GaN:Mg/AlGaN, and that difficulty of epitaxial growth causes density of defects to be high, which results in a relatively low electrical conductivity and a poor injection efficiency, to better improve the electrical performance of the light-emitting device, the ratio of the first radius (R1) to the ampacity is configured to range from 0.15 to 0.25 (e.g., larger through holes are needed if the current stays the same) to avoid a high operating voltage.

The ampacity is defined as a maximum operating current or a maximum terminal current of the light-emitting device. For example, the ampacity can be calculated by using lamp bead current of a terminal product according to user manual. The number of UV device packages currently circulating in the market is countable by the naked eye or may be observed using an optical microscope, in combination with the number of lamp beads and arrangement of the lamp beads, the lamp bead current of a single light-emitting device can be calculated. In some embodiments, to avoid current crowding, the rated ampacity ranges from 40 mA to 500 mA.

The first electrode 21 is electrically connected to the first semiconductor layer 121. The first electrode 21 may be a single-layered, a double-layered, or a multilayered structure, e.g., a stacked structure made of materials such as Ti/Al, Ti/Al/Ti/Au, Ti/Al/Ni/Au, V/AI/Pt/Au, and the like. In some embodiments, the first electrode 21 is formed directly in a corresponding one of the through holes 14 of the semiconductor epitaxial structure 12. The first semiconductor layer 121 has a high aluminum composition, and the first electrode 21 undergoes a high temperature fusion-bonding to form an alloy after being deposited in the corresponding one of the through holes 14, thereby forming a good ohmic contact with the first semiconductor layer 121.

The second electrode 22 is electrically connected to the second semiconductor layer 123. The second electrode 22 may be made of a transparent conductive material or a metal material (e.g., Ni alloy metal or Pa alloy metal, etc.), which may be selected based on doping of a surface of the second semiconductor layer 123 (e.g., a p-type GaN surface layer). In some embodiments, the second electrode 22 is made of a transparent conductive material that may include indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO), or zinc oxide (ZnO), but the present disclosure is not limited thereto.

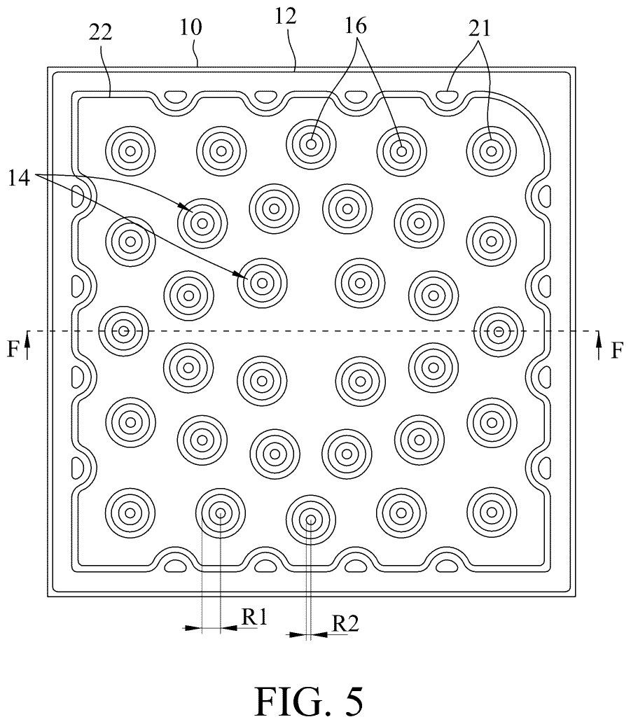

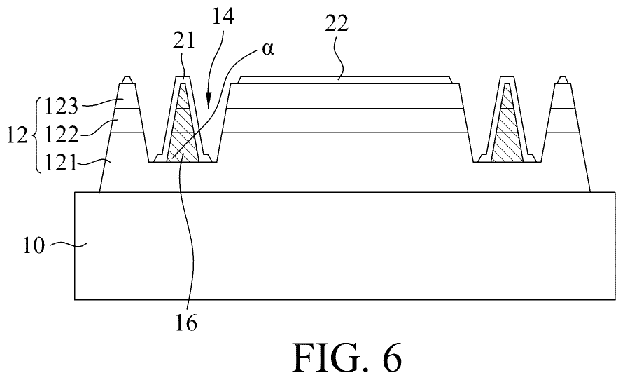

Referring to FIGS. 5 and 6, FIG. 5 is a schematic top view of a light-emitting device according to a second embodiment of the disclosure. FIG. 6 is a schematic view taken along line F-F of FIG. 5. Compared to the light-emitting device shown in FIG. 1, the difference between the light-emitting device of this embodiment and that of FIG. 1 resides in that, when the semiconductor epitaxial structure 12 is viewed from above the light-emitting device, the through holes 14 respectively include a plurality of protrusions 16. In the conventional light-emitting device, after the electrodes are disposed, an interior of the conventional light-emitting device may not form into a flattened surface. In addition, the interior of the conventional light-emitting device has a large unfilled space (i.e., a hollowed structure) that affects packaging and thrust strength of the conventional light-emitting device). In this disclosure, a flattening effect is achieved by virtue of disposing the protrusions 16. In addition, considering that the semiconductor epitaxial structure 12 of the light-emitting device is relatively thin, and a depletion layer (a depletion layer of each of the p-type and the n-type semiconductor layers) of each of the first semiconductor layer 121 and the second semiconductor layer 123 is relatively thin, the protrusions 16 may adjust current spreading in a horizontal direction perpendicular to the stacking direction, thereby expanding area of current spreading and avoiding downward electrical damage.

An inclined angle (α) each of the protrusions 16 may range from 45° to 70°, in some embodiments, from 55° to 60°, and a height of each of the protrusions 16 may range from 500 nm to 800 nm. An upper surface of each of the protrusions 16 is flush with the upper surface of the second semiconductor layer 123. Each of the protrusions 16 has a second radius (R2). Each of the protrusions 16, when being viewed from above the semiconductor epitaxial structure 12, has a round shape, and the second radius (R2) is a radius of the round shape. To avoid current crowding, a ratio of the second radius (R2) to the first radius (R1) ranges from 0.05 to 0.3, and the second radius (R2) may ranges from 0.6 μm to 45 μm. When each of the protrusions 16 has a square-like shape or an irregular closed-loop shape, the second radius (R2) may be approximated by taking a radius of an internal circle of the square-like shape or the irregular closed-loop shape.

In this embodiment, when the semiconductor epitaxial structure 12 is viewed from above the light-emitting device, each of the protrusions 16 is located at a center of a respective one of the through holes 14 for simplification of the process.

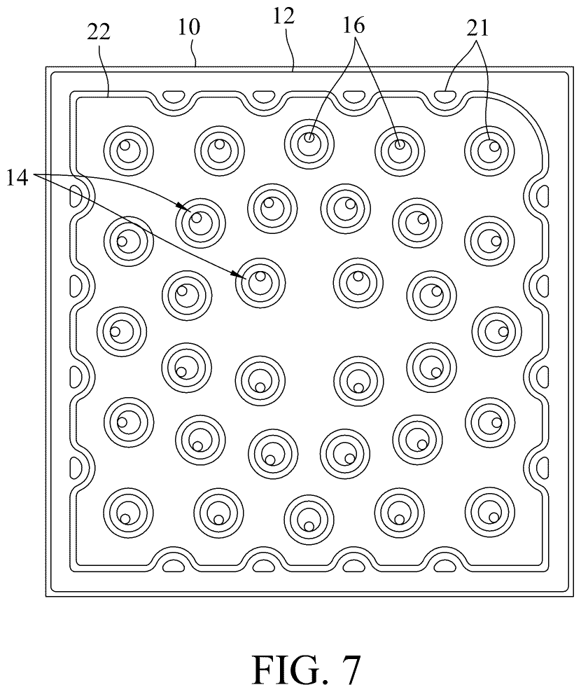

However, the disclosure is not limited thereto, and in other embodiments, as shown in FIG. 7, each of the protrusions 16 is located inside the respective one of the through holes 14 and is off-center to be more proximate to a boundary edge of the semiconductor epitaxial structure 12, thereby allowing electricity injected in a central region of the semiconductor epitaxial structure 12 to uniformly flow to a peripheral region of the semiconductor epitaxial structure 12 so as to increase carrier density per area unit in the peripheral region and to enhance the electroluminescence performance of the light-emitting device.

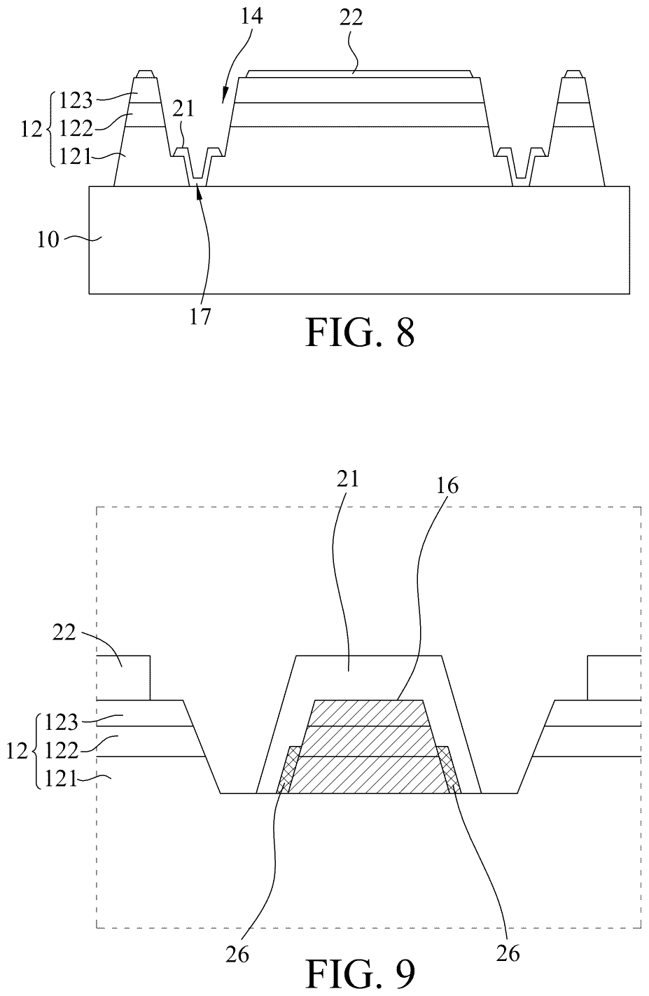

In addition, in some embodiments, as shown in FIG. 8, the protrusions 16 may be replaced by recess structures 17. That is to say, when the semiconductor epitaxial structure 12 is viewed from above the light-emitting device, the through holes 14 respectively include the recess structures 17, which may also adjust current spreading in the horizontal direction, thereby expanding the area of current spreading and avoiding downward electrical damage. A ratio of a diameter of each of the recess structures 17 to the first radius (R1) ranges from 0.05 to 0.3. The purpose of either the recess structures 17 or the protrusions 16 is to form islands inside the semiconductor epitaxial structure 12, so that current does not flow therethrough, thereby adjusting current spreading in the horizontal direction, and expanding the area of current spreading and avoiding downward electrical damage.

In some embodiments, as shown in FIG. 9, which is an enlarged schematic view of another version of one of the protrusions 16. Compared to the protrusions 16 of FIG. 6 which still creates significant void spaces despite of having an improved flattening effect and optimized diffraction, in this embodiment, by virtue of disposing cover electrodes 26 on each of the protrusions 16 (i.e., the cover electrodes 26 are connected to sidewalls of the protrusions 16), flatness and diffraction are improved, the amount of material used for the first electrodes 21 is reduced, and areas of the unfilled spaces are lessened. Each of the cover electrodes 26 climbs upwardly along a sidewall of a respective one of the protrusions 16 from a bottom of the respective one of the protrusions 16. A height of each of the cover electrodes 26 ranges from 100 nm to 400 nm, thereby increasing downward current spreading of the protrusions 16 and improving the electroluminescence performance of the light-emitting device.

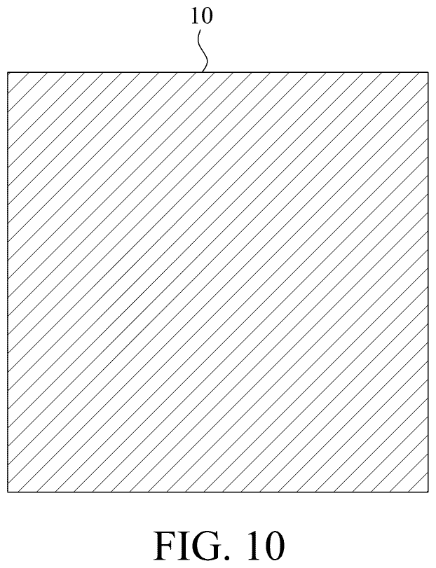

Referring to FIGS. 10 to 13, a method for manufacturing the light-emitting device shown in FIG. 5 is described below. FIGS. 10 to 13 are schematic views illustrating consecutive process steps of the manufacturing method of the light-emitting device.

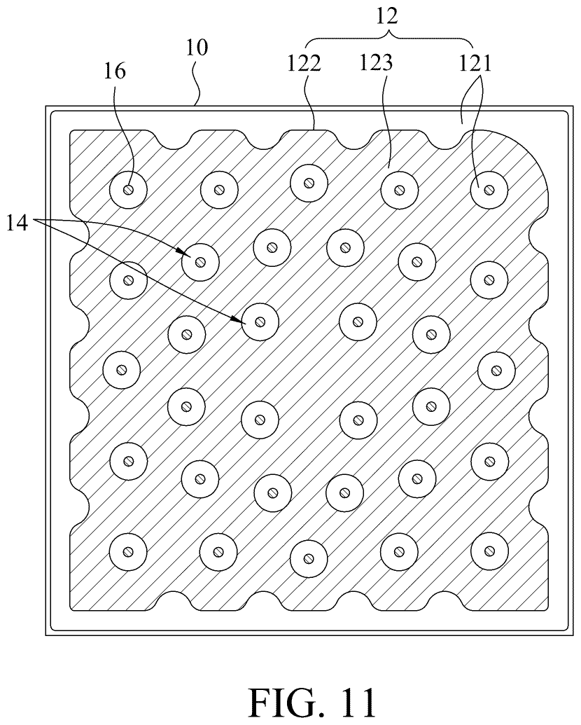

First, the substrate 10 is provided as shown in FIG. 10. Next, the semiconductor epitaxial structure 12 is disposed on the substrate 10 as shown in FIG. 11. The semiconductor epitaxial structure 12 includes the first semiconductor layer 121, the active layer 122, and the second semiconductor layer 123 sequentially stacked in such order on the substrate 10. Then, the semiconductor epitaxial structure 12 is etched from the second semiconductor layer 123 downwardly to reach the first semiconductor layer 121 to form the through holes 14. In FIG. 11, the shaded area in is an area of the second semiconductor layer 123 that is not etched, and portions of the first semiconductor layer 121 that are not etched inside the through holes 14 are the protrusions 16, i.e., composition of the protrusions 16 may be the same as that of the first semiconductor layer 121 for simplification of the process. Subsequently, chemical or physical etching is used to selectively etch out the peripheral region of the semiconductor epitaxial structure 12 to expose the substrate 10 so as to form a cutting channel for subsequent processes, such as dicing.

Furthermore, it should be noted that in other embodiments, the protrusions 16 may be disposed on the first semiconductor layer 121 by other means. In addition, in the case of forming the recess structures 17, the through holes 14 may be formed first and then further etching is conducted in the through holes 14 to form the recess structures 17.

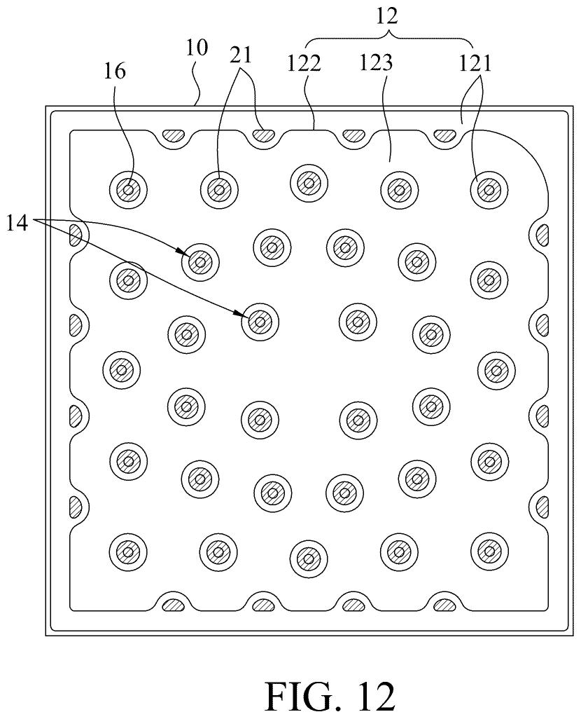

Then, as shown in FIG. 12, the first electrodes 21 are disposed on the first semiconductor layer 121 where some of the first electrodes 21 are respectively disposed in the through holes 14. The shaded area in FIG. 12 shows where the first electrodes 21 are located.

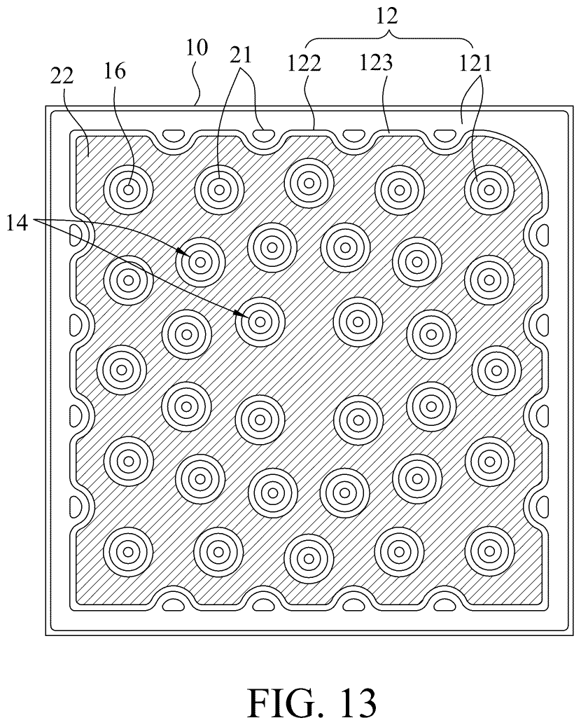

Finally, as shown in FIG. 13, the second electrode 22 is disposed on the second semiconductor layer 123. An area of the second electrode 22 is smaller than an area of the second semiconductor layer 123. The shaded area in FIG. 13 shows where the second electrode 22 is located.

The above description only describes one method for manufacturing the light-emitting device shown in FIG. 5. The present disclosure is not limited thereto, but is only used to exemplify one method for manufacturing the light-emitting device.

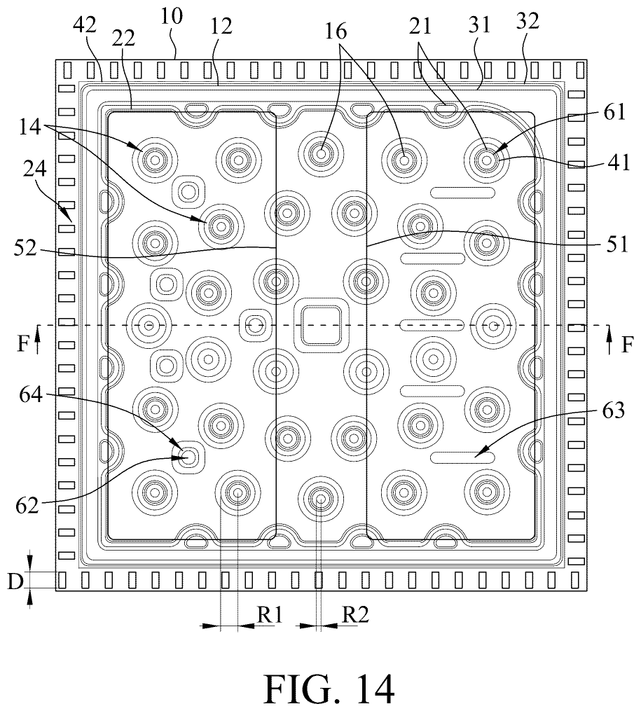

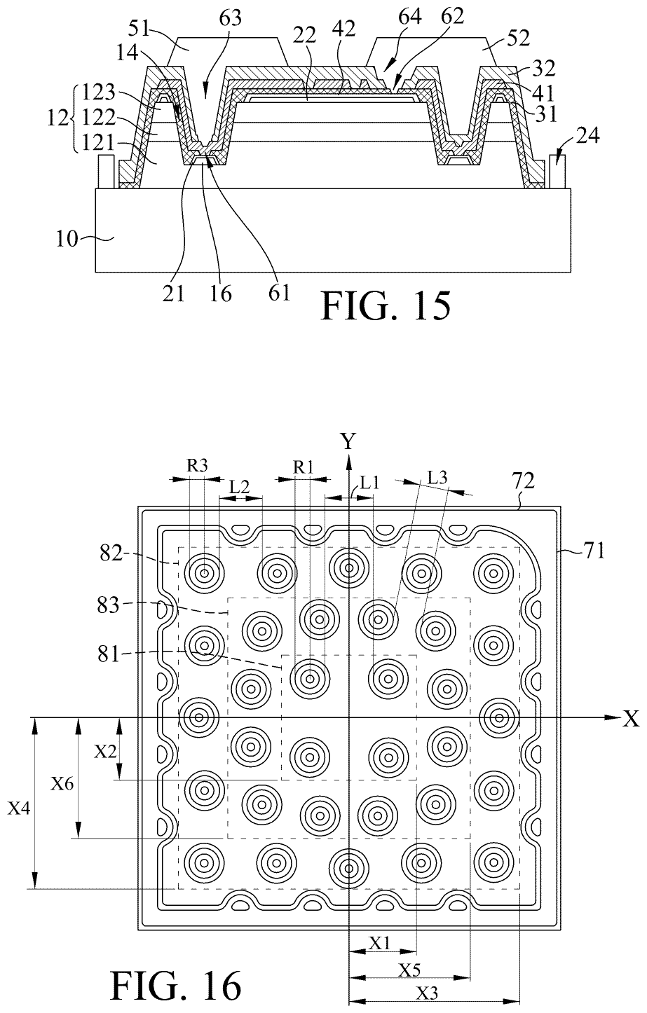

Referring to FIGS. 14 and 15, FIG. 14 is a schematic top view of a light-emitting device according to a third embodiment of the present disclosure, and FIG. 15 is a schematic sectional view taken along line F-F of FIG. 14. The difference between the light-emitting device of this embodiment and that of FIG. 5 resides in that, the substrate 10 includes a cooling zone 24. The cooling zone 24 is a region of the substrate 10 that is not covered by the semiconductor epitaxial structure 12. By designing the cooling zone 24 having a wide width adjacent to a periphery of the substrate 10 (the width of the cooling zone 24 may occupy 3% to 15% of length of a short side of the chip), the amount of sideward light exiting paths is increased and heat buildup is reduced. The forming of the cooling zone 24 at the periphery of the substrate 10 may improve heat dissipation and prevent thermal damage to the internal structure. In some embodiments, to improve heat dissipation, a ratio of a length (D) of the cooling zone 24 to the first radius (R1) ranges from 1.2 to 1.5.

The cooling zone 24 may be formed by the following methods: 1) by disposing separate electrode blocks along the periphery of the substrate 10, 2) by disposing a heat dissipation structure at the periphery of the substrate 10, 3) or by disposing a dam and filling cooling gel. In this embodiment, the second method is adopted, and the cooling zone 24 includes a plurality of heat dissipating structures. A length of each of the heat dissipating structures ranges from 0.6 μm to 200 μm, a thickness of each of the heat dissipating structures ranges from 0.3 μm to 20 μm, and a width of the heat dissipating structures ranges 0.6 μm to 200 μm. The lower limit of 0.6 μm is selected based on consideration for etching precision. The upper limit of 200 μm is selected due to the greatest size of the chip being 500 mil. In some embodiments, the length of each of the heat dissipating structures ranges from 10 μm to 50 μm, the thickness of each of the heat dissipating structures ranges from 3 μm to 9 μm, and the width of the heat dissipating structures ranges 2.5 μm to 7.5 μm, thereby dissipating heat effectively and ensuring electroluminescence performance of the light-emitting device. A minimum distance between adjacent ones of the heat dissipating structures ranges from 0.6 μm to 200 μm. In some embodiments, the minimum distance between adjacent ones of the heat dissipating structures ranges from 2.5 μm to 7.5 μm. Due to absorption problems at the p-side of the UV light-emitting device, a central region and a peripheral region of the UV light-emitting device need to be differentiated from one another. The cooling zone 24 is formed in the peripheral region (the cooling zone 24 may be a ring-shaped area surrounding the periphery of the substrate 10 and having a width that ranges from 7.6 μm to 223.5 μm). A ratio of a length of the cooling zone 24 to the first radius (R1) ranges from 1.2 to 1.5 for better electroluminescence performance. In some embodiments, the ratio of the length of cooling zone 24 to the first radius (R1) ranges from 1.2 to 1.5.

In some embodiments, as shown in FIG. 15, the light-emitting device may further include a first insulation layer 31, a second insulation layer 32, a first protection electrode 41, a second protection electrode 42, a first pad 51, and a second pad 52. The first insulation layer 31 covers the first electrode 21 and the second electrode 22. The first insulation layer 31 has a first opening 61 and a second opening 62. The first opening 61 exposes the first electrode 21 and the second opening 62 exposes the second electrode 22. The first protection electrode 41 is electrically connected to the first electrode 21 through the first opening 61, and the second protection electrode 42 is electrically connected to the second electrode 22 through the second opening 62. The second insulation layer 32 covers the first protection electrode 41 and the second protection electrode 42, and the second insulation layer 32 has a third opening 63 and a fourth opening 64.

The first protection electrode 41, in addition to spreading current, also protects the first electrode 21 below and provides support for raising the first electrode 21. In some embodiments, the first protection electrode 41 completely covers the first electrode 21 so as to prevent precipitation of metals from the first electrode 21 (e.g., precipitation of aluminum). The first electrode 21 may be made of Cr, Pt, Au, Ni, Ti, Al, or combinations thereof. In some embodiments, a surface of the first electrode 21 is made of Ti or Cr so as to establish a stable bonding with the first protective electrode 41 and an adjacent layer thereof. The second protection electrode 42 may be made of Cr, Pt, Au, Ni, Ti, Al, or combinations thereof. In some embodiments, a surface of the second protection electrode 42 is made of Ti or Cr so as to establish a stable bonding with the second protective electrode 42 and an adjacent layer thereof.

Each of the first insulation layer 31 and the second insulation layer 32 includes a non-conductive material. The non-conductive material may be an inorganic material or a dielectric material. The inorganic material may include silica gel. The dielectric material may include an electrically insulating material such as aluminum oxide, silicon nitride, silicon oxide, titanium oxide, or magnesium fluoride.

For example, the first insulation layer 31 may be made of silicon dioxide, silicon nitride, titanium oxide, tantalum oxide, niobium oxide, barium titanate, or combinations thereof. Such combinations may be formed, for example, by alternatively stacking two materials with different refractive indices, thereby forming a Bragg reflective layer structure.

The first pad 51 is electrically connected to the first protection electrode 41 through the third opening 63, and the second pad 52 is electrically connected to the second protection electrode 42 through the fourth opening 64. Each of the first pad 51 and the second pad 52 may be metal pads that may be formed at the same time in a process utilizing the same material, and thus have the same composition.

FIG. 16 is a schematic view of the light-emitting device of FIG. 5 under a coordinate system. Referring to FIGS. 5 and 16, when the semiconductor epitaxial structure 12 is viewed from above the light-emitting device, the semiconductor epitaxial structure 12 has a center that is used as an origin of the coordinate system. An x-axis of the coordinate system is a perpendicular line extending from the origin of the coordinate system to a first edge 71 of the semiconductor epitaxial structure 12, and a y-axis of the coordinate system is a perpendicular line extending from the origin of the coordinate system to a second edge 72 of the semiconductor epitaxial structure 12. The first edge 71 is connected to the second edge 72. In some embodiments, the first edge 71 is substantially perpendicularly connected to the second edge 72. A first loop line 81 loops around the center of the semiconductor epitaxial structure 12 and is displaced from the origin by a first distance (X1) along a positive direction and a negative direction of the x-axis and by a second distance (X2) in a positive direction and a negative direction of the y-axis. A second loop line 82 loops around the first loop line 81 and is displaced from the origin by a third distance (X3) along a positive direction and a negative direction of the x-axis and by a fourth distance (X4) in a positive direction and a negative direction of the y-axis. Each of the third distance (X3) and the fourth distance (X4) is greater than each of the second distance (X2) and the first distance (X1). That is to say, each of the third distance (X3) and the fourth distance (X4) is greater than the first distance (X1), and each of the third distance (X3) and the fourth distance (X4) is greater than the second distance (X2). The third distance (X3) may be 1.5 times to 3.75 times the first distance (X1), and the fourth distance (X4) may be 1.5 times to 3.75 times the second distance (X2). The first distance (X1) may range from 50 μm to 160 μm, the second distance (X2) may range from 50 μm to 160 μm, the third distance (X3) may range from 150 μm to 480 μm, and the fourth distance (X4) may range from 150 μm to 480 μm. The first distance (X1) may be the same as or different from the second distance (X2), and the third distance (X3) may be the same as or different from the fourth distance (X4).

Two adjacent ones of the through holes 14 within the first loop line 81 have a first spacing (L1) therebetween, and two adjacent ones of the through holes 14 disposed between the first loop line 81 and the second loop line 82 have a second spacing (L2) therebetween. The first spacing (L1) is greater than the second spacing (L2). By adjusting the density of through holes 14, carrier crowding is reduced, thereby optimizing distribution of the through holes 14 within the loop lines 81, 82 so as to reduce current crowding in the central region of the semiconductor epitaxial structure 12 and to prevent the thermal damage caused by current crowding in the central region, which may burn holes out of the active layer 122. Such configuration may prevent the direct downward electrical damage and the direct breakdown of the P/N junction, thereby improving the anti-ESD performance of the light emitting device.

In some embodiments, each of the first loop line 81 and the second loop line 82 has a rectangular shape, but the present disclosure is not limited herein. Each of the first loop 81 and the second loop 82 may also have a symmetrical shape, such as a circle, a polygonal shape, etc., as long as the first spacing (L1) between the two adjacent ones of the through holes 14 within the first loop 81 is greater than the second spacing (L2) of the two adjacent ones of the through holes 14 disposed between the first loop 81 and the second loop 82.

It should be noted that, by virtue of the first spacing (L1) being greater than the second spacing (L2) alone, the anti-ESD performance of the light-emitting device is already enhanced. That is to say, in this embodiment, the ratio of the first radius (R1) to the ampacity is not limited to range from 0.1 to 0.4.

A third loop line 83 loops around the first loop line 81 and is displaced from the origin by a fifth distance (X5) along a positive direction and a negative direction of the x-axis and by a sixth distance (X6) along a positive direction and a negative direction of the y-axis. Each of the fifth distance (X5) and the sixth distance (X6) is greater than each of the second distance (X2) and the first distance (X1), and each of the fifth distance (X5) and the sixth distance (X6) is smaller than each of the third distance (X3) and the fourth distance (X4). Two adjacent ones of the through holes 14 disposed between the third loop line (83) and the first loop line (81) have a third spacing (L3) therebetween. The first spacing (L1) is greater than the third spacing (L3), and the third spacing (L3) is no smaller than said second spacing (L2). Such configuration may improve thermal characteristics of the light-emitting device. The fifth distance (X5) may range from 100 μm to 320 μm, and the sixth distance (X6) may range from 100 μm to 320 μm.

In some embodiments, to further improve the thermal performance of the light-emitting device, each of the through holes 14 disposed within the first loop line 81 has the first radius (R1), and the ratio of the first spacing (L1) to the first radius (R1) ranges from 0.8 to 1.5. Each of the through holes 14 disposed within the second loop line 82 has a third radius (R3), and the ratio of the second spacing (L2) to the third radius (R3) ranges from 0.6 to 1.2.

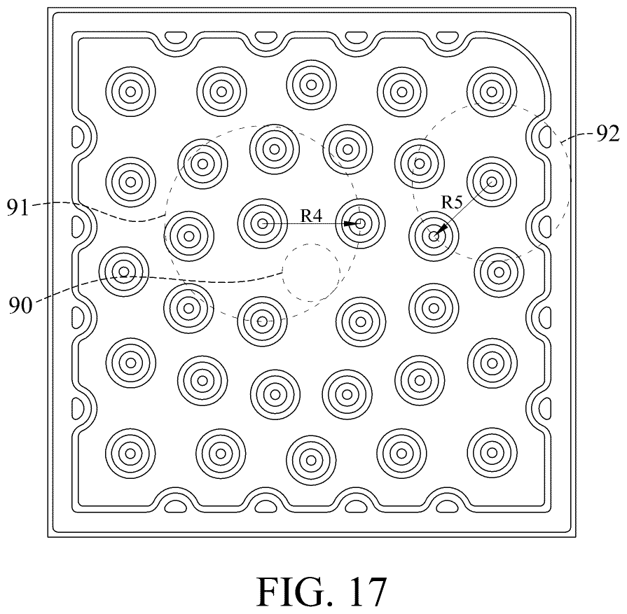

Referring to FIG. 17 in combination with FIG. 5, FIG. 17 is the same view as FIG. 5, but having a first circle 91 and a second circle 92. When the semiconductor epitaxial structure 12 is viewed from above the light-emitting device, the light-emitting device has an ejector pin region 90. The ejector pin region 90 is located at the center of the semiconductor epitaxial structure 12. The through holes 14 do not overlap the ejector pin region 90. A center-to-center distance between two adjacent ones of the through holes 14 near the ejector pin region 90 forms a radius (R4) of the first circle 91 which is centered at a center of one of the two adjacent ones of the through holes 14. A center-to-center distance between another two adjacent ones of the through holes 14 near the boundary of the semiconductor epitaxial structure 12 forms a radius (R5) of the second circle 92 which is centered at a center of one of the another two adjacent ones of the through holes 14. The first circle 91 is greater than the second circle 92 in size. That is to say, the radius (R4) of the first circle 91 is greater than the radius (R5) of the second circle 92. By virtue of adjusting distribution of the through holes 14, carrier crowding may be reduced. Distribution of the through holes 14 inside each of the first circle 91 and the second circle 92 is optimized so current crowding at the central region of the semiconductor epitaxial structure 12 is reduced. Such configuration may prevent the thermal damage caused by current crowding in the central region, which may burn holes out of the active layer 122. Such configuration may also prevent the direct downward electrical damage and the direct breakdown of the P/N junction, thereby improving the anti-ESD performance of the light emitting device.

The through holes 14 near the ejector pin region 90 may refer to the through holes 14 that are spaced apart from the ejector pin region by a distance that ranges from 15 μm to 60 μm. In some embodiments, the distance ranges from 35 μm to 40 μm. The through holes 14 near the boundary edge of the semiconductor epitaxial structure 12 may refer to the through holes 14 that are spaced apart from the boundary edge by a distance that ranges from 20 μm to 70 μm. In some embodiments, the distance ranges from 45 μm to 47 μm. To further improve the anti-ESD performance of the light-emitting device, an area of the first circle 91 is at least two times an area of the second circle 92.

It should be noted that, as long as the first circle 91 is greater than the second circle 92, the anti-ESD performance of the light-emitting device may be improved. That is to say, in this embodiment, the ratio of the first radius (R1) to the ampacity is not limited to range from 0.1 to 0.4.

The through holes 14 within the first circle 91 are not evenly distributed, and the through holes 14 within the second circle 92 are evenly distributed, thereby rendering density of carrier per unit area in the first circle 91 being smaller that than of the second circle 92. By virtue of the density of carrier per unit area near the boundary edge of the semiconductor epitaxial structure 12 being greater than that near the center of the semiconductor epitaxial structure 12, injection density near the boundary edge is enhanced (considering waveguide effect of photons, light exiting near the boundary edge is more significant), thereby improving light-exiting of the light-emitting device. In addition, when the subsequently disposed first pad 51 and second pad 52 are formed in the second circle 92, a greater carrier density per unit area in the second circle 92 may facilitate heat dissipation of the first pad 51 and the second pad 52.

The carrier density per unit area may be understood as a current density per unit area that is injected perpendicularly to the active layer 122. Because positions and distribution of the through holes 14 may affect current spreading, current density of the light-emitting device is not uniformly distributed. Current density near specific through holes 14 may be calculated by dividing an injection current by an area of the first semiconductor layer 121 in a reference circle (e.g., the first circle 91 or the second circle 92) of the through holes 14. In this embodiment, the area of the first semiconductor layer 12 in each of the first circle 91 and the second circle 92 is substantially the same, the injection current is substantially the same, the fourth radius (R4) is greater than the fifth radius (R5) (i.e., the area of the first circle 91 is greater than the second circle 92), and therefore a carrier density per area unit of the first circle 91 is smaller than the carrier density per area unit of the second circle 92.

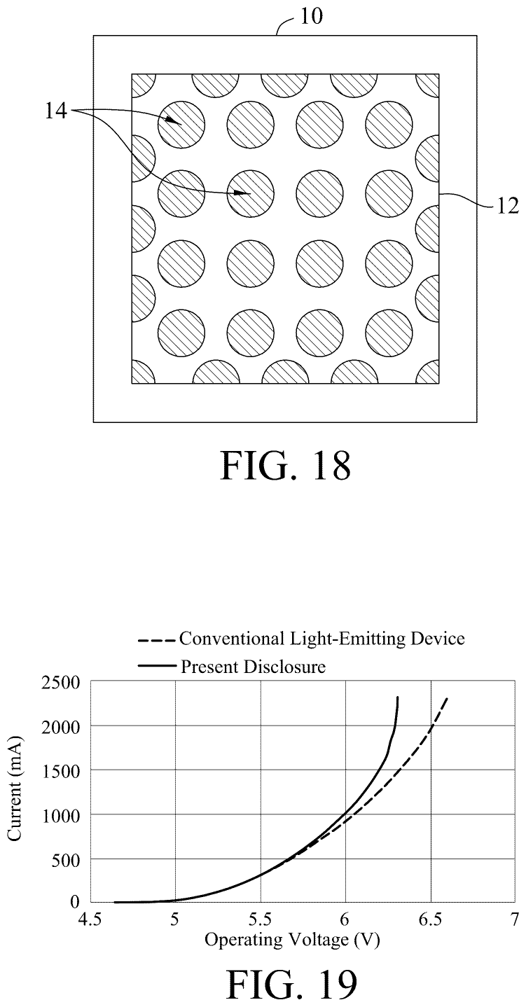

The manner in which the through holes 14 are arranged is not limited to the one shown in FIG. 17. In some embodiments, referring to FIG. 18, the through holes 14 in the central region are arranged a right angled rectangular array. The through holes 14 at the boundary edge are arranged in a denser hexagonal array.

Referring to FIG. 19, the horizontal axis represents operating voltage, and the vertical axis represents current. When the current is the same, the operating voltage of the light-emitting device is 0.3 V lower than that of the conventional light-emitting device. This demonstrates an improved electroluminescence performance of the light-emitting device of the disclosure.

The present disclosure further provides a light-emitting apparatus that includes a plurality of the light-emitting devices as described in any of the previous embodiments. The light-emitting devices may be micro light-emitting devices, mini light-emitting devices or standard light-emitting devices, which may be arranged in hundreds or thousands on a packaging substrate to form a light source of a backlight display or a RGB display panel.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a semiconductor epitaxial structure including a first semiconductor layer, an active layer, and a second semiconductor layer sequentially stacked in such order in a stacking direction, and including a plurality of through holes, said plurality of through holes extending downwardly in a direction from said second semiconductor layer to said first semiconductor layer, said plurality of through holes exposing a portion of a surface of said first semiconductor layer;
wherein said light-emitting device has an ampacity, each of said plurality of through holes having a first radius, a ratio of said first radius to said ampacity ranges from 0.1 to 0.4.

2. The light-emitting device as claimed in claim 1, wherein said ampacity is defined as a maximum operating current or a maximum terminal current of said light-emitting device.

3. The light-emitting device as claimed in claim 1, wherein said ampacity ranges from 40 mA to 500 mA.

4. The light-emitting device as claimed in claim 1, wherein said first radius ranges from 6 μm to 150 μm.

5. The light-emitting device as claimed in claim 1, wherein a total area of projections of said plurality of through holes on an imaginary plane perpendicular to said stacking direction occupies 10% to 50% of an area of a projection of said semiconductor epitaxial structure on said imaginary plane.

6. The light-emitting device as claimed in claim 1, wherein said plurality of through holes respectively include a plurality of protrusions, each of said plurality of protrusions having a second radius, a ratio of said second radius to said first radius ranges from 0.05 to 0.3.

7. The light-emitting device as claimed in claim 6, wherein when said semiconductor epitaxial structure is viewed from above said light-emitting device, each of said plurality of protrusions is located at a center of a respective one of said plurality of through holes.

8. The light-emitting device as claimed in claim 6, wherein when said semiconductor epitaxial structure is viewed from above said light-emitting device, each of said plurality of protrusions is located inside a respective one of said plurality of through holes and is off-center to be more proximate to a boundary edge of said semiconductor epitaxial structure.

9. The light-emitting device as claimed in claim 6, wherein said second radius ranges from 0.6 μm to 45 μm.

10. The light-emitting device as claimed in claim 6, wherein when said semiconductor epitaxial structure is viewed from above said light-emitting device, said plurality of through holes respectively include a plurality of recess structures, a ratio of a diameter of each of said plurality of recess structures to said first radius ranging from 0.05 to 0.3.

11. The light-emitting device as claimed in claim 1, further comprising a substrate, a first electrode and a second electrode, said semiconductor epitaxial structure being disposed on said substrate, said first semiconductor layer being disposed between said substrate and said active layer, said first electrode being electrically connected to said first semiconductor layer, said second electrode being electrically connected to said second semiconductor layer,
wherein when said semiconductor epitaxial structure is viewed from above said light-emitting device, said plurality of through holes are arranged in arrays, said substrate including a cooling zone, said cooling zone being a region of said substrate that is not covered by said semiconductor epitaxial structure.

12. The light-emitting device as claimed in claim 11, wherein a ratio of a length of said cooling zone to said first radius ranges from 1.2 to 1.5.

13. The light-emitting device as claimed in claim 11, wherein said cooling zone includes a plurality of heat dissipating structures, a length of each of said plurality of heat dissipating structures ranging from 0.6 μm to 200 μm, a thickness of each of said plurality of heat dissipating structures ranging from 0.3 μm to 20 μm, a width of each of said plurality of heat dissipating structures ranging from 0.6 μm to 200 um, a minimum distance between adjacent ones of said plurality of heat dissipating structures ranging from 0.6 μm to 200 μm.

14. The light-emitting device as claimed in claim 11, further comprising a first insulation layer, a second insulation layer, a first protection electrode, a second protection electrode, a first pad and a second pad, said first insulation layer covering said first electrode and said second electrode, said first insulation layer having a first opening and a second opening, said first protection electrode being electrically connected to said first electrode) through said first opening, said second protection electrode being electrically connected to said second electrode through said second opening, said second insulation layer covering said first protection electrode and said second protection electrode, said second insulation layer having a third opening and a fourth opening, said first pad being electrically connected to said first protection electrode through said third opening, said second pad being electrically connected to said second protection electrode through said fourth opening.

15. The light-emitting device as claimed in claim 1, wherein:
when said semiconductor epitaxial structure is viewed from above said light-emitting device, said semiconductor epitaxial structure has a center used as an origin of a coordinate system, an x-axis of the coordinate system being a perpendicular line extending from the origin of the coordinate system to a first edge of said semiconductor epitaxial structure, a y-axis of the coordinate system being a perpendicular line extending from the origin of the coordinate system to a second edge of said semiconductor epitaxial structure, the first edge being perpendicularly connected to the second edge;
a first loop line loops around said center of said semiconductor epitaxial structure and is displaced from the origin by a first distance along a positive direction and a negative direction of the x-axis and by a second distance in a positive direction and a negative direction of the y-axis; and
a second loop line loops around said first loop line and is displaced from the origin by a third distance along a positive direction and a negative direction of the x-axis and by a fourth distance in a positive direction and a negative direction of the y-axis;
each of said third distance and said fourth distance being greater than each of said second distance and said first distance, two adjacent ones of said plurality of through holes within said first loop line having a first spacing therebetween, two adjacent ones of said plurality of through holes disposed between said first loop line and said second loop line having a second spacing therebetween, said first spacing being greater than said second spacing.

16. The light-emitting device as claimed in claim 15, wherein said first distance ranges from 50 μm to 160 μm, said second distance ranges from 50 μm to 160 μm, said third distance) ranges from 150 μm to 480 μm, and said fourth distance ranges from 150 μm to 480 μm.

17. The light-emitting device as claimed in claim 15, wherein:
a third loop line loops around said first loop line and is displaced from the origin by a fifth distance along a positive direction and a negative direction of the x-axis and by a sixth distance in a positive direction and a negative direction of the y-axis;
each of said fifth distance and said sixth distance being greater than each of said second distance and said first distance, each of said fifth distance and said sixth distance being smaller than each of said third distance and said fourth distance, two adjacent ones of said plurality of through holes disposed between said third loop line and said first loop line having a third spacing therebetween, said first spacing being greater than said third spacing, said third spacing being no smaller than said second spacing.

18. The light-emitting device as claimed in claim 17, wherein said fifth distance ranges from 100 μm to 320 μm, and said sixth distance ranges from 100 μm to 320 μm.

19. The light-emitting device as claimed in claim 1, wherein:
when said semiconductor epitaxial structure is viewed from above said light-emitting device, said light-emitting device has an ejector pin region, said ejector pin region being located at a center of said semiconductor epitaxial structure, said plurality of through holes nonoverlapping said ejector pin region; and
a center-to-center distance between two adjacent ones of said plurality of through holes near said ejector pin region forms a radius of a first circle which is centered at a center of one of said two adjacent ones of said plurality of through holes, a center-to-center distance between another two adjacent ones of said plurality of through holes near a boundary edge of said semiconductor epitaxial structure forms a radius of a second circle which is centered at a center of one of said another two adjacent ones of said plurality of through holes, said first circle being greater than said second circle in size.

20. The light-emitting device as claimed in claim 19, wherein said plurality of through holes within said first circle are not evenly distributed, and said plurality of through holes within said second circle are evenly distributed.

21. A light-emitting apparatus, comprising the light-emitting device as claimed in claim 1.
